(19) United States
(12) Patent Application Publication
(10) Pub. No.: US 2004/0012385 A1
(43) Pub. Date: Jan. 22, 2004

(54) Apparatus and method for generating an offset voltage for angular position calculations

(76) Inventor: Richard A. Kirkpatrick II, Richardson, TX (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/197,204

(22) Filed: Jul. 16, 2002

(51) Int. Cl. G01B 7/30; G01R 33/09

(52) U.S. Cl. 324/207.21; 324/207.25

(57) ABSTRACT

An apparatus and method thereof for generating an offset voltage utilized in generating angular position estimates is disclosed. A first bridge circuit comprising a first plurality of resistors is generally arranged in a bridge configuration, wherein the first plurality of resistors are coupled to a first amplifier, such that a first voltage having a sinusoidal component thereof is generated at an output of the first amplifier. A second bridge circuit comprising a second plurality of resistors can also be arranged in a bridge configuration, wherein the second plurality of resistors are coupled to a second amplifier, such that a second voltage having a cosine component thereof is generated at an output of the second amplifier. Additionally, an offset voltage amplifier circuit is generally coupled to the first bridge circuit and the second bridge circuit. The offset voltage amplifier circuit can be further comprised of at least one amplifier coupled to a node wherein at least two resistors are also coupled, such that the offset voltage amplifier circuit generates an offset voltage that is utilized to generate angular position estimations.

### TECHNICAL FIELD

The present invention is related generally to magnetic and angular position sensors. The present invention is related also to bridge circuits. The present invention is related also to anisotropic magneto-resistance (AMR) bridge circuits utilized in association with magnetic sensors.

### BACKGROUND OF THE INVENTION

Magneto-resistive sensors have been utilized for the contactless detection of changes in state, such as the measurement of an angular position of a rotatably mounted part. Such magneto-resistive sensors typically include magnetic field-dependent resistors that are connected in a bridge circuit configuration and through which a control current is fed. When such a magneto-resistive sensor is influenced by a magnetic field, a voltage can be established such that the magnitude of the voltage depends on the magnitude and direction of the magnetic field associated with the sensor. The relationship between the bridge voltage and the magnetic field direction can be utilized in a contactless AMR (anisotropic magneto resistance) sensor, for example, for detecting angular position of a rotatably mounted part. If precise measurement is to be possible at all, then a zero point must first be defined, or a calibration of the sensor must be performed.

A magneto-resistive sensor, which can be constructed as a bridge circuit, may be acted upon by a magnetic field oriented in a particular manner, such that a definite control current can be applied to the current contacts of the bridge circuit. The voltage that is then established at the other contacts is measured on an ongoing basis. The magneto-resistive sensor is processed with the aid of a laser until such time as the offset voltage, when no magnetic field is applied, becomes equal to zero. Such magneto-resistive sensors are thus ideally suited for angular position applications and for use as angular position sensors.

Referring to FIGS. 1 and 2, it is well known in the art that two anisotropic magneto resistive (hereafter referred to as AMR) bridges can be topologically constructed to provide a sine signal and a cosine signal from which the angle of rotation, alpha, can be calculated. Further, it is well known in the art that signal conditioning can be applied to the differential outputs to provide gain and conversion from differential to single-ended outputs. It is also well known in the art that the process of chip singulation (e.g., wafer sawing) and chip packaging generate a small redistribution of the offset voltages. The non-zero offset voltages contribute to error in the angle calculations. Previous methods, for example, have utilized offset voltage compensation techniques for measuring and storing the offset voltages in non-volatile memory. These “measure and store” methods are potentially very accurate but typically come with a high cost, associated mostly with the calibration. Other methods, for example, estimate the common-mode offset voltages by finding the positive and negative peaks of the signals and averaging them. These “peak-to-peak averaging” methods are generally not as accurate as the “measure and store” methods, but typically come with a more moderate cost, associated mostly with the calibration.

Angular position sensors that utilize magneto-resistive bridge circuits generally provide two voltages: a sine signal and a cosine, signal. These signals are typically level-shifted to the center of the supply voltage range. Thus, the voltages are created by the sum of a sinusoidal component plus a DC common-mode offset voltage. The angular position calculations thereof require only the sine and cosine components. Thus, an estimate must be made of the common-mode offset voltage to extract the sinusoidal components. Present methods and devices require costly calibration or simply cannot be used if the range of angular rotation is too small. The two dominant methods utilized thus far involve measurement of the offset voltages and storage thereof in a non-volatile memory, or measurement of positive and negative peak voltages, followed by the calculation of an offset voltage and storage in a non-volatile memory. The present invention is directed to a solution to the aforementioned drawbacks of the prior art, as further explained herein, by providing a third voltage, which supplies the offset voltage directly. Such a configuration can eliminate the need for a calibration routine and non-volatile memory.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an apparatus and method for providing an offset voltage, which can be used to estimate angular position calculations, derived from angular position sensors.

It is, therefore, another aspect of the present invention to provide a circuit composed of at least two bridge circuits and at least one offset voltage amplifier circuit, which are utilized to generate offset voltages for angular position calculations.

It is yet another aspect of the present invention to provide an improved sensing apparatus for use with angular position sensors.

It is yet another aspect of the present invention to provide an improved sensing apparatus for use with magnetic angular position sensors.

The above and other aspects of the invention can be achieved as is now described. The present invention generally discloses an apparatus and method for generating an offset voltage utilized in generating angular position estimates. A first bridge circuit comprising a first plurality of resistors is generally arranged in a bridge configuration, wherein the first plurality of resistors are coupled to a first amplifier, such that a first voltage having a sinusoidal component is generated at an output of the first amplifier. A second bridge circuit comprising a second plurality of resistors can also be arranged in a bridge configuration, wherein the second plurality of resistors are coupled to a second amplifier, such that a second voltage having a cosine component is generated at an output of the second amplifier. Additionally, an offset voltage amplifier circuit further includes at least one amplifier coupled to a node wherein at least two resistors are also coupled, such that the offset voltage amplifier circuit generates an offset voltage that is utilized to generate angular position estimations. The offset voltage amplifier circuit is coupled to the first bridge circuit and the second bridge circuit. The offset voltage amplifier circuit comprises at least one amplifier coupled, at an input of at least one amplifier, to a first resistor and a second resistor, such that the offset voltage amplifier circuit generates an offset voltage that is utilized to generate angular position estimations. The first bridge circuit is centroidally collocated with the second bridge circuit, wherein at least one circuit element associated with the first bridge circuit is rotated by forty-five degrees relative to at least one circuit element associated with the second bridge circuit.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates two prior art circuits indicative of the manner in which AMR bridges can be configured, such that the resulting electrical signal is found at the differential output of each bridge thereof;

FIG. 2 illustrates a graph of a prior art bridge or amplifier output voltage versus angle of rotation and associated angle calculations;

FIG. 3 illustrates a schematic diagram of a circuit implemented in accordance with a preferred embodiment of the present invention; and

FIG. 4 illustrates a plot of error equations in accordance with a preferred embodiment of the present invention.

### DETAILED DESCRIPTION OF THE INVENTION

The particular values and configurations discussed in these non-limiting examples can be varied and are cited merely to illustrate an embodiment of the present invention and are not intended to limit the scope of the invention.

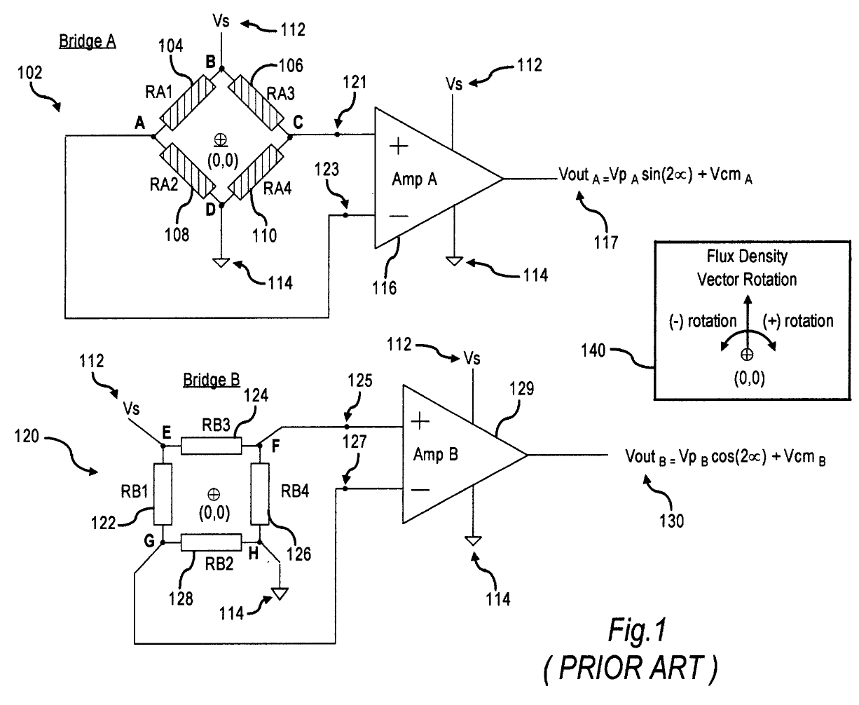

FIG. 1 illustrates prior art circuits 102 and 120, which are indicative of AMR bridge configurations (i.e., Bridge A and Bridge B), such that the resulting electrical signal is found at the differential output of each bridge thereof. Circuit 102 (i.e., Bridge A) generally includes a resistor 104 coupled to a resistor 106 at node B. Node B is also coupled to a power supply 112 (i.e., Vs). Resistor 106 is also coupled to resistor 110 at node C, which is further coupled to a positive input 121 of an amplifier 116. Resistor 110 is further coupled to a resistor 108 at node D. Resistor 108 is coupled to resistor 104 at node A. Node D is also coupled to a ground 114. Node A is also coupled to a negative input 123 of amplifier 116. Amplifier 116 (i.e., Amp A) is in turn coupled to ground 114 and power supply 112. Resistors 104, 106, 108, and 110 are respectively labeled RA1, RA3, RA2 and RA4 in FIG. 1. An output 117 is generated from amplifier 116, wherein Vout_{A}=Vp_{A}sin(2α)+Vcm_{A}.

FIG. 1 also depicts a circuit 120 (i.e., Bridge 2), which generally includes a resistor 122 coupled to a resistor 124 at node E. Resistor 124 is in turn coupled to a resistor 126 at node F. Resistor 126 is coupled to a resistor 128 at node H. Resistor 128 is coupled to resistor 122 at node G. In FIG. 1, resistors 122, 124, 126, and 128 are respectively labeled RB1, RB3, RB4, and RB2. Node H is coupled to ground 114, while node E is coupled to power supply 112 (Vs). An amplifier 129 (i.e., Amp B) is coupled to node F at a positive input 125 of amplifier 129. Amplifier 129 is coupled to node G at a negative input 127 of amplifier 129. An output 130 is generated from amplifier 129, wherein Vout_{B}=VP_{B}cos(2α)+Vcm_{B}. Note additionally, as indicated at block 140, that Bridge A is centroidally collocated with Bridge B, and Bridge A elements are rotated by 45 degrees relative to the Bridge B elements illustrated in FIG. 1.

The present invention disclosed herein is thus generally directed toward a technique and apparatus thereof for reducing errors involved in calculations for determining the angular rotation, θ, from a sin(2θ) signal and a cos(2θ) signal when the range of rotation is less than 180 degrees. It is well known in the art that two anisotropic magneto-resistive (hereafter referred to as AMR) bridges can be topologically constructed to provide the aforementioned quadrature signals. It is also well known in the art that signal conditioning can be applied to the differential outputs to provide gain and conversion from differential to single-ended outputs 117 and 130 as illustrated in FIG. 1. The present invention provides an independent voltage output, which is statistically closer to the measured common-mode offset voltages than can be provided by the “peak-to-peak averaging” method discussed earlier.

Note generally that when the range of angular rotation falls from between 135 degrees to 180 degrees, the positive peak and the negative peak of each signal may be obtained and averaged to calculate the common-mode offset voltage for each signal. Equations 1 through 4 below illustrate the generic calculations for each signal, where Vpp and Vnp refer to the positive peak and negative peak responses, respectively. The “A” subscripts refer to the sin(2θ) signal and the “B” subscripts refer to the cos(2θ) signal. The dominant error in this case is non-symmetry in the positive and negative peak magnetic responses as shown below in Equations 1 and 2, respectively. The effect of this symmetry error is shown in Equations 3 to 8. If the symmetry error, e_{sym}, and the net magnetic response mismatch error, eₚₖ, are both much less than one, which is nearly always the case, then the error approximations in Equation 8 are reasonably accurate.

Vpp=Vp(1+e_{sym})+Vcm Eq. 1

where, e_{sym}≡magnetic symmetry error within a signal.

Vnp=−Vp+Vcm Eq.2

$$\begin{matrix}{Vp}_{calc} = \frac{Vpp - Vnp}{2} = Vp + ( \frac{Vp}{2} ) {e}_{sym} & Eq . 3 \\ {Vcm}_{calc} = \frac{Vpp + Vnp}{2} = Vcm + ( \frac{Vp}{2} ) {e}_{sym} & Eq . 4\end{matrix}$$

$${e}_{pm} = ( \frac{{Vp}_{A}}{{Vp}_{B}} ) - 1 \qquad Eq . 5$$

where, eₚₘ≡magnetic mis-match error between the signals.

$${e}_{p k} = [ \frac{( 1 + \frac{{e}_{symB}}{2} )}{( 1 + {e}_{p m} ) ( 1 + \frac{{e}_{symA}}{2} )} ] - 1 \qquad Eq . 6$$

where, eₚₖ≡net magnetic error between the signals.

$$\begin{matrix}\begin{matrix}{θ}_{calc} = \frac{{Tan}^{- 1} [ \frac{( 1 + {e}_{p k} ) ( {Vout}_{A} - {Vcm}_{calcA} )}{( {Vout}_{B} - {Vcm}_{calcB} )} ]}{2} \\ = \frac{{Tan}^{- 1} [ \frac{( 1 + {e}_{p k} ) [ {Vp}_{A} ( 1 + \frac{{e}_{symA}}{2} ) sin ( 2 θ ) - ( \frac{{Vp}_{A}}{2} ) {e}_{symA} ]}{{Vp}_{B} ( 1 + \frac{{e}_{symB}}{2} ) cos ( 2 θ ) - ( \frac{{Vp}_{B}}{2} ) {e}_{symB}}}{2}\end{matrix} & Eq . 7 \\ error \approx [ \frac{{e}_{symB}}{4} sin ( 2 θ ) - \frac{{e}_{symA}}{4} cos ( 2 θ ) ] ( \frac{180}{π} ) & Eq . 8\end{matrix}$$

$${error}_{max} \approx + / - \frac{{e}_{rss}}{4} ( \frac{180}{π} ) deg .$$

where, eᵣₛₛ≡root-sum-squared symmetry error.

When the range of angular rotation is less than 135 degrees, at least one of the signals does not contain both the positive peak and the negative peak. And, in the case of angular rotation less than 90 degrees, neither signal contains both the positive peak and the negative peak. In both of these cases the “peak-to-peak averaging” method extrapolates between the two signals, which increases the error in the angle calculations.

First, the case where the range of angular rotation is both less than 135 degrees and greater than or equal to 90 degrees must be considered. It is assumed that both peaks of the sin(2θ) signal as shown in Equations 9 and 10 can be measured, but only the positive peak of the cos(2θ) signal may be measured, which is indicated in Equation 13 herein. The key assumption is that any difference in the positive peak voltages between the signals is attributed entirely to common-mode voltage mismatch. This is incorporated mathematically by extrapolations #1 and #2, which is illustrated below with respect Equations 14 and 15. The dominant error in this case is the net magnetic response mismatch, eₚₖ, which cannot be cancelled as was illustrated previously in Equations 6 and 7. The effect of this magnetic response mismatch error coupled with the symmetry error is shown in Equations 11 to 17. If the individual errors are each much less than one, and the magnitude of eₚₖ is at least half the magnitude of e_{sym}, both of which conditions are nearly always the case, then the net error approximations in Equation 17 are reasonably accurate. The maximum error is dependent on the relative values of the individual errors.

When the angular rotation is less than 90 degrees, the best that can be achieved by “peak-to-peak averaging” methods is the measurement of the positive peak of one signal and the negative peak of the other signal and extrapolate between the signals.

Vpp_{A}=Vp_{A}(1+e_{symA})+VcmA Eq. 9

Vnp_{A}=−Vp_{A}+Vcm_{A} Eq. 10

$$\begin{matrix}{Vp}_{calcA} = \frac{{Vpp}_{A} - {Vnp}_{A}}{2} = {Vp}_{A} + ( \frac{{Vp}_{A}}{2} ) {e}_{symA} & Eq . 11 \\ {Vcm}_{calcA} = \frac{{Vpp}_{A} + {Vnp}_{A}}{2} = {Vcm}_{A} + ( \frac{{Vp}_{A}}{2} ) {e}_{symA} & Eq . 12\end{matrix}$$

Vpp_{B}=Vp_{B}(1+e_{symB})+Vcm_{B} Eq. 13

Vp_{calcB}≈Vp_{calcA} extrapolaion #1 Eq.14

$${Vcm}_{calcB} \approx {Vpp}_{B} - {Vp}_{calcA} = {Vcm}_{B} + ( \frac{{Vp}_{B}}{2} ) {e}_{symB} + ( {Vp}_{A} ) {e}_{p k} extrapolaion \#2 \qquad Eq . 15$$

$$\begin{matrix}\begin{matrix}{θ}_{calc} = \frac{{Tan}^{- 1} [ \frac{( {Vout}_{A} - {Vcm}_{calcA} )}{( {Vout}_{B} - {Vcm}_{calcB} )} ]}{2} \\ \approx \frac{{Tan}^{- 1} [ \frac{{Vp}_{A} ( 1 + \frac{{e}_{symA}}{2} ) sin ( 2 θ ) - ( \frac{{Vp}_{A}}{2} ) {e}_{symA}}{{Vp}_{B} ( 1 + \frac{{e}_{symB}}{2} ) cos ( 2 θ ) - ( \frac{{Vp}_{B}}{2} ) {e}_{symB} - ( {Vp}_{A} ) {e}_{p k}} ]}{2}\end{matrix} & Eq . 16 \\ {error}_{sym} \approx [ \frac{{e}_{symB}}{4} sin ( 2 θ ) - \frac{{e}_{symA}}{4} cos ( 2 θ ) ] ( \frac{180}{π} ) & Eq . 17 \\ {error}_{p k} \approx [ \frac{{e}_{p k}}{2} ( sin ( 2 θ ) - \frac{1}{2} sin ( 4 θ ) ] ( \frac{180}{π} ) & \end{matrix}$$

error ₙₑₜ≈error _{sym}+error ₚₖ

$${error}_{max} \approx + / - ( \frac{{e}_{symB}}{4} + \frac{{e}_{p k}}{2} ) ( \frac{180}{π} ) deg . when \vert {e}_{p k} \vert \geq \frac{\vert {e}_{symA} \vert + \vert {e}_{symB} \vert}{2}$$

The key assumptions are that both signals have the same magnetic response and the same common-mode offset voltage. This is incorporated mathematically by extrapolation #1 as shown in Equation 19. The dominant errors in this case are the net magnetic response mismatch, eₚₖ, which cannot be cancelled as was shown in equations 6 and 7, and the differential common-mode offset voltage mismatch, eₒₛ. The effect of these mismatch errors coupled with the symmetry error is shown in Equations 18 to 23. If the individual errors are each much less than one, which is nearly always the case, then the net error approximations in equation 23 are reasonably accurate. The maximum error is dependent on the relative values of the individual errors.

$$\begin{matrix}{Vpp}_{A} = {Vp}_{A} ( 1 + \frac{{e}_{symA}}{2} ) + {Vcm}_{A} & Eq . 18 \\ {Vnp}_{B} = - {Vp}_{B} ( 1 + \frac{{e}_{symB}}{2} ) + {Vcm}_{B} & Eq . 19\end{matrix}$$

$$\begin{matrix}{Vcm}_{calcA} = {Vcm}_{calcB} \approx {Vcm}_{calc} = \frac{{Vpp}_{A} + {Vnp}_{B}}{2} extrapolation \#1 \\ = ( \frac{{Vcm}_{A} + {Vcm}_{B}}{2} ) - ( \frac{{Vp}_{A}}{2} ) {e}_{p k} & Eq . 20 \\ {e}_{os} = \frac{{Vcm}_{A} - {Vcm}_{B}}{Vs} = \frac{{e}_{osA} - {e}_{osB}}{2} where , {e}_{os} ≡ differential {Vos}_{c m} mis - match . & Eq . 21\end{matrix}$$

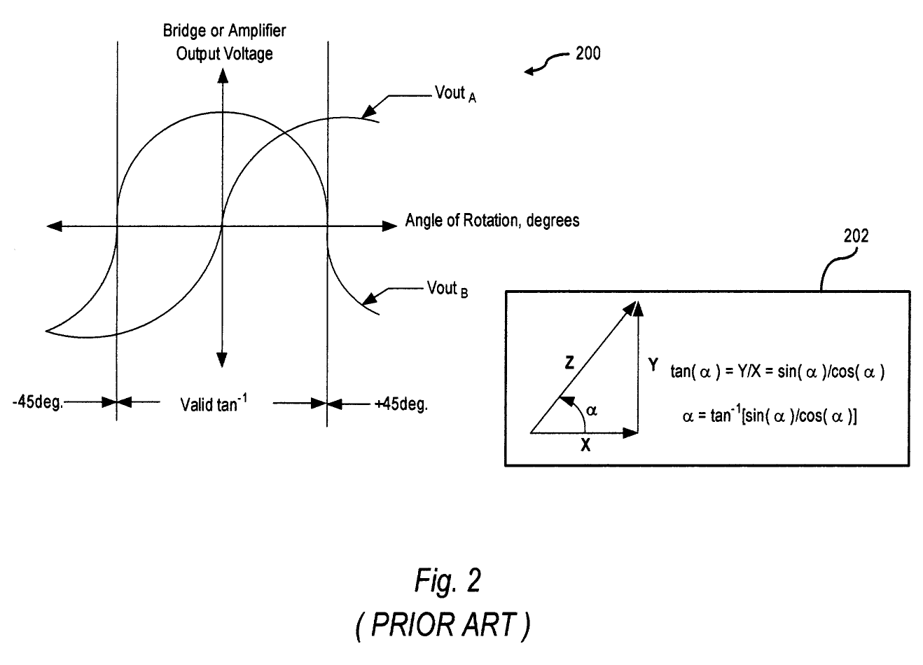

Thus, the aforementioned equations demonstrate the increasing complexity of the calculations and extrapolations with the “peak-to-peak averaging” method. As the range of angular rotation falls below 135 degrees, and then 90 degrees, the number of error terms increases. Obviously, if the range of angular rotation falls below 45 degrees, then the “peak-to-peak averaging” method cannot even be utilized. Note that FIG. 2 depicts a graph 200 illustrating a prior art bridge or amplifier output voltage versus angle of rotation. FIG. 2 also depicts, as illustrated at block 202, how an angle (alpha) can be shifted (sine to cosine).

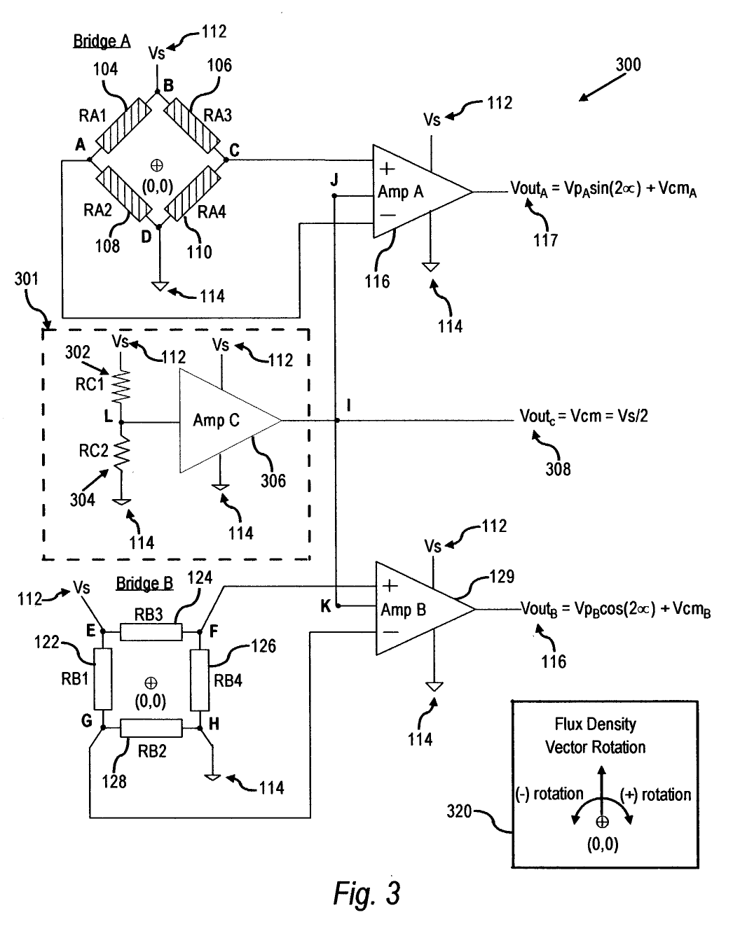

In accordance with the present invention, a third signal can thus be provided, which is equal to one-half of the supply voltage, Vs, as illustrated in FIG. 3. FIG. 3 illustrates a schematic diagram of a circuit 300, which is implemented in accordance with a preferred embodiment of the present invention. Note that in FIGS. 1 and 3, like parts are indicated by like reference numerals. Thus, amplifier 116 is connected by an input J of amplifier 116 to an input K of amplifier 129. Inputs J and K are coupled to node 1, which comprises an output 308 of an amplifier 306. Amplifier 306 is coupled to ground 114 and power supply 112.

A resistor 302, which is labeled RC1, is generally coupled to a resistor 304, which is labeled RC2, at node L. Resistor 302 is further coupled to power supply 112, while resistor 304 is further coupled to ground 114. Node L is input to amplifier 306 (i.e., Amp C), such that the output 308 at node I is generally provided by Vout_{c}=Vcm=Vs/2. Thus, Bridge A is centroidally collocated with Bridge B, and Bridge A elements are rotated by 45 degrees relative to Bridge B, as indicated at block 320. Thus, resistors 302 and 304, together with amplifier 306 form an offset voltage amplifier circuit 301 that is coupled to a first bridge circuit (i.e., Bridge A) and a second bridge circuit (i.e., Bridge B), such that offset voltage amplifier circuit 301 generates an offset voltage (i.e., voltage 308) that can be utilized to generate angular position estimations.

The key assumptions are that both signals have the same magnetic response and the same common-mode offset voltage of one-half of the supply voltage. The angle calculation now uses the one-half Vs voltage as measured from the third output instead of determined by an extrapolation. The dominant errors in this case are the net magnetic response mismatch, eₚₖ, which cannot be cancelled as shown in equations 6 and 7, and the common-mode offset voltage mismatch, eₒₛ. The effect of these mismatch errors coupled with the symmetry error is shown in equations 24 to 27. If the individual errors are each much less than one, which is nearly always the case, then the net error approximations in equation 27 are reasonably accurate. The maximum error is dependent on the relative values of the individual errors.

$$\begin{matrix}{Vcm}_{A} = ( \frac{Vs}{2} ) ( 1 + {e}_{osA} ) & Eq . 24 \\ {Vcm}_{B} = ( \frac{Vs}{2} ) ( 1 + {e}_{osB} ) & Eq . 25\end{matrix}$$

where, e_{osA}≡Signal A mis-match from half Vs.

where, e_{osB}≡Signal B mis-match from half Vs.

Eq. 26 θcalc

$${θ}_{calc} = \frac{{Tan}^{- 1} [ \frac{( {Vout}_{A} - \frac{Vs}{2} )}{( {Vout}_{B} - \frac{Vs}{2} )} ]}{2} \qquad Eq . 26$$

$$\approx \frac{{Tan}^{- 1} [ \frac{{Vp}_{A} ( 1 + \frac{{e}_{sym A}}{2} ) sin ( 2 θ ) + ( \frac{Vs}{2} ) {e}_{os A}}{{Vp}_{B} ( 1 + \frac{{e}_{sym B}}{2} ) cos ( 2 θ ) + ( \frac{Vs}{2} ) {e}_{os B}} ]}{2}$$

$$\begin{matrix}{error}_{sym} \approx [ \frac{( {e}_{sym A} - {e}_{sym B} )}{8} sin ( 4 θ ) ] ( \frac{180}{π} ) \\ {error}_{pm} \approx [ \frac{{e}_{p m}}{4} sin ( 4 θ ) ] ( \frac{180}{π} ) \\ {error}_{os} \approx [ \frac{{e}_{os A}}{\sqrt{2}} cos ( 2 θ ) - \frac{{e}_{os B}}{\sqrt{2}} sin ( 2 θ ) ] ( \frac{180}{π} ) \\ {error}_{net} \approx {error}_{sym} + {error}_{p m} + {error}_{os} \\ {error}_{max} \approx [ \frac{( {e}_{sym A} - {e}_{sym B} )}{8} + \frac{{e}_{p m}}{4} + {e}_{os} ] ( \frac{180}{π} ) deg . or \\ {error}_{max} \approx [ \frac{( {e}_{sym A} - {e}_{sym B} )}{- 8} + \frac{{e}_{p m}}{- 4} + \frac{{e}_{os A} + {e}_{os B}}{2} ] ( \frac{180}{π} ) deg . \\ {error}_{max} \approx [ \frac{( {e}_{sym A} - {e}_{sym B} )}{4} + \frac{{e}_{p m}}{2} - {e}_{os B} ] ( \frac{180}{π} ) deg . \end{matrix} \qquad Eq . 27$$

Comparing Equation 27 to Equations 17 and 23, it is seen that the error term due to the net magnetic response mismatch, eₚₖ, in Equations 17 and 23 is not present in Equation 27. Also, the offset voltage mismatch error term, e_{osB}, for the peak-to-peak error in Equation 27 will be statistically smaller than the differential voltage mismatch error term, eₒₛ, in Equation 23, as it is a function of a single voltage instead of a difference in two independent voltages. To further illustrate the performance provided by the present invention as compared to the examples given in the Background section, statistical analyses of the maximum error expressions are provided in Equations 28 to 32.

$$\begin{matrix}{σ}_{epk} = \sqrt{( \frac{2 {σ}_{esym}^{2}}{4} + {σ}_{epm}^{2} )} from Eq . 6 & Eq . 28 \\ {σ}_{Eq 8} = \sqrt{( \frac{2 {σ}_{esym}^{2}}{16} )} ( \frac{180}{π} ) deg . from Eq . 8 & Eq . 29 \\ {σ}_{Eq 17} = \sqrt{( \frac{ {σ}_{esym}^{2}}{16} + \frac{ {σ}_{epk}^{2}}{4} )} ( \frac{180}{π} ) deg . from Eq . 17 & Eq . 30 \\ {σ}_{Eq 23} = \sqrt{( \frac{2 {σ}_{esym}^{2}}{64} + \frac{ {σ}_{epm}^{2}}{16} + \frac{ {σ}_{epk}^{2}}{225} + {σ}_{eos}^{2} )} ( \frac{180}{π} ) deg . from Eq . 21 , 23 or \\ {σ}_{Eq 23} = \sqrt{( \frac{2 {σ}_{esym}^{2}}{64} + \frac{ {σ}_{epm}^{2}}{16} + \frac{ {σ}_{epk}^{2}}{8.5} + \frac{{σ}_{eos}^{2}}{27} )} ( \frac{180}{π} ) deg . from Eq . 21 , 23 & Eq . 31 \\ {σ}_{Eq 27} = \sqrt{( \frac{2 {σ}_{esym}^{2}}{64} + \frac{ {σ}_{epm}^{2}}{16} + {σ}_{eos}^{2} )} ( \frac{180}{π} ) deg . from Eq . 27 & Eq . 32\end{matrix}$$

Table 1, below shows the resulting standard deviation in the maximum angular error using a range of typically encountered standard deviations for the individual error terms. Table 1, also indicates a variety of error notes for respective cases. Clearly from Table 1 it can be observed that when the range of angular rotation is large enough to measure the positive and negative peaks of both signals, a cost versus performance trade-off exists. In all other cases the present invention results in significantly smaller or equivalent maximum errors, thereby permitting the associated cost to be reduced without sacrificing performance.

TABLE 1

| Error | | | | | σₘₐₓ | |
|---|---|---|---|---|---|---|
| Notes | σ_{esym} | σₑₚₘ | σₑₚₖ | σₑₒₛ | (degrees) | Calculation Notes |
| Case 1a | 0.00667 | — | — | — | 0.14 | measure both peaks on each |
| | | | | | | signal |
| Case 1b | 0.00667 | 0.0167 | 0.0174 | — | 0.51 | measure both peaks on 1 signal |
| Case 1c | 0.00667 | 0.0167 | 0.0174 | 0.0035 | 0.42 | measure 1 peak on each signal |
| Case 1d | 0.00667 | 0.0167 | 0.0174 | 0.0035 | 0.32 | measure ½ Vs |
| Case 2a | 0.00333 | — | — | — | 0.07 | measure both peaks on each |
| | | | | | | signal |
| Case 2b | 0.00333 | 0.01 | 0.01 | — | 0.29 | measure both peaks on 1 signal |
| Case 2c | 0.00333 | 0.01 | 0.01 | 0.00175 | 0.25 | measure 1 peak on each signal |
| Case 2d | 0.00333 | 0.01 | 0.01 | 0.00175 | 0.18 | measure ½ Vs |
| Case 3a | 0.00333 | — | — | — | 0.07 | measure both peaks on each |
| | | | | | | signal |
| Case 3b | 0.00333 | 0.0044 | 0.005 | — | 0.15 | measure both peaks on 1 signal |
| Case 3c | 0.00333 | 0.0044 | 0.005 | 0.00175 | 0.12 | measure 1 peak on each signal |
| Case 3d | 0.00333 | 0.0044 | 0.005 | 0.00175 | 0.12 | measure ½ Vs |
| Case 4a | 0.00333 | — | — | — | 0.07 | measure both peaks on each |
| | | | | | | signal |
| Case 4b | 0.00333 | 0.001 | 0.0025 | — | 0.09 | measure both peaks on 1 signal |
| Case 4c | 0.00333 | 0.001 | 0.0025 | 0.00175 | 0.11 | measure 1 peak on each signal |
| Case 4d | 0.00333 | 0.001 | 0.0025 | 0.00175 | 0.11 | Measure ½ Vs |

Cases 1 and 2 represent the lowest cost in which no adjustment is performed to reduce the magnetic mismatch distribution and shows that the present invention has significantly smaller maximum error. Cases 3 and 4 represent deliberate adjustment of the magnetic mismatch distribution at some point in the manufacturing process. Note in Case 3 that even a moderate amount of reduction in the magnetic mismatch distribution can nearly minimize the maximum error using the invention method. Case 4 illustrates that extreme reduction in the magnetic mismatch distribution allows the performance of all the methods to converge.

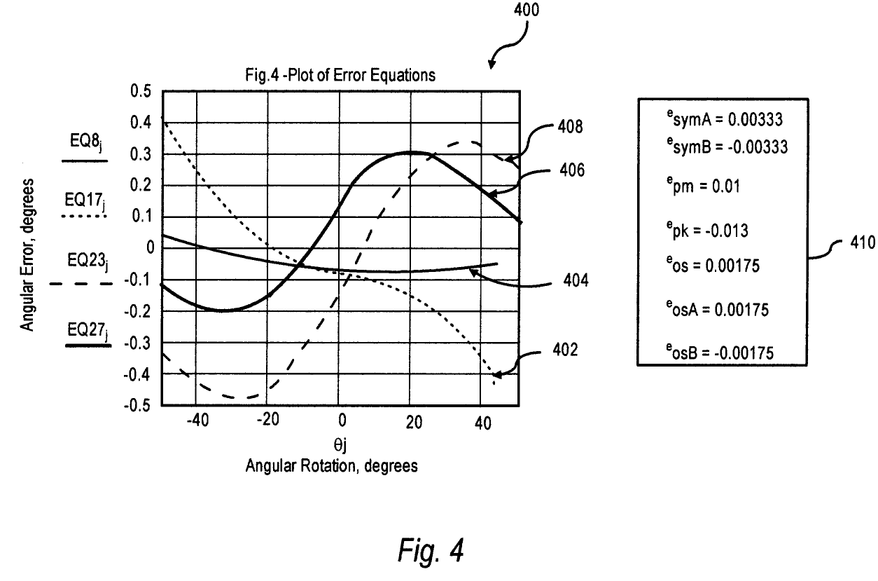

A final illustration of the performance provided by the present invention with respect to the other given examples is provided in FIG. 4, which illustrates a plot of the net error functions found in Equations 8, 17, 23, and 27 utilizing the error magnitudes from Case 2 in Table 1. FIG. 4 depicts a graph 400 of a plot of error equations, in accordance with a preferred embodiment of the present invention. Graph 400 illustrates angular errors, in degrees, versus angular rotation, in degrees. Lines 402, 404, 406, and 408 indicate the results of the error equations, while associated error values are illustrated at block 410.

The present invention has many advantages. First, the present invention can be used over a broader range of applications as compared to the “peak-to-peak averaging” methods. Second, for applications where the range of angular rotation is less than 135 degrees (i.e., at least one of the signals does not contain both the positive peak and the negative peak), the present invention achieves smaller, or at least comparable, accuracy with respect to the “peak-to-peak averaging” methods. Third, for applications where the range of angular rotation is less than 180 degrees, the present invention has a considerably lower cost than either the “measure and store” or the “peak-to-peak averaging” methods as it does not require calibration.

Based on the foregoing, it can thus be appreciated that the present invention generally discloses an apparatus and method thereof for generating an offset voltage utilized in generating angular position estimates. A first bridge circuit comprising a first plurality of resistors is generally arranged in a bridge configuration, wherein the first plurality of resistors are coupled to a first amplifier, such that a first voltage having a sinusoidal component thereof is generated at an output of the first amplifier. A second bridge circuit comprising a second plurality of resistors can also be arranged in a bridge configuration, wherein the second plurality of resistors are coupled to a second amplifier, such that a second voltage having a cosine component thereof is generated at an output of the second amplifier.

Additionally, an offset voltage amplifier circuit is generally coupled to the first bridge circuit and the second bridge circuit. The offset voltage amplifier circuit can include at least one amplifier coupled to a node wherein at least two resistors are also coupled, such that the offset voltage amplifier circuit generates an offset voltage that is utilized to generate angular position estimations. The first bridge circuit is centroidally collocated with the second bridge circuit, wherein at least one circuit element associated with the first bridge circuit is rotated by forty-five degrees relative to at least one circuit element associated with the second bridge circuit.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

The embodiments of the invention in which an exclusive property or right is claimed are defined as follows:

1. An apparatus for generating an offset voltage utilized in generating angular position estimates, said apparatus comprising:
a first bridge circuit comprising a first plurality of resistors arranged in a first bridge configuration;
a second bridge circuit comprising a second plurality of resistors arranged in a second bridge configuration; and
an offset voltage amplifier circuit that is coupled to said first bridge circuit and said second bridge circuit, wherein said offset voltage amplifier circuit generates an offset voltage that is utilized to generate angular position estimations.

2. The apparatus of claim 1 wherein said first plurality of resistors are coupled to a first amplifier, wherein a first voltage having a sinusoidal component thereof is generated at an output of said first amplifier.

3. The apparatus of claim 1 wherein said second plurality of resistors are coupled to a second amplifier, wherein a second voltage having a cosine component thereof is generated at an output of said second amplifier.

4. The apparatus of claim 1 wherein said offset voltage amplifier circuit comprises at least one amplifier.

5. The apparatus of claim 4 wherein said at least one amplifier is coupled to a node to which at least two resistors are coupled.

6. The apparatus of claim 1 wherein said first bridge circuit comprises an AMR bridge circuit.

7. The apparatus of claim 1 wherein said second bridge circuit comprises an AMR bridge circuit.

8. The apparatus of claim 2 wherein said first plurality of resistors comprises at least four resistors.

9. The apparatus of claim 3 wherein said second plurality of resistors comprises at least four resistors.

10. The apparatus of claim 1 wherein said offset voltage comprises a common-mode offset voltage.

11. The apparatus of claim 1 wherein said first bridge circuit is centroidally collocated with said second bridge circuit.

12. The apparatus of claim 11 wherein at least one circuit element associated with said first bridge circuit is rotated by forty-five degrees-relative to at least one circuit element associated with said second bridge circuit.

13. An apparatus for generating an offset voltage utilized in generating angular position estimates, said apparatus comprising:
a first bridge circuit comprising a first plurality of resistors arranged in a first bridge configuration, wherein said first plurality of resistors is coupled to a first amplifier, such that a first voltage having a sinusoidal component thereof is generated at an output of said first amplifier;
a second bridge circuit comprising a second plurality of resistors arranged in a second bridge configuration, wherein said second plurality of resistors is coupled to a second amplifier, such that a second voltage having a cosine component thereof is generated at an output of said second amplifier;
an offset voltage amplifier circuit that is coupled to said first bridge circuit and said second bridge circuit, wherein said offset voltage amplifier circuit comprises at least one amplifier coupled to a node wherein a first resistor and a second resistor are also coupled, such that said offset voltage amplifier circuit generates an offset voltage that is utilized to generate angular position estimations; and
wherein said first bridge circuit is centroidally collocated with said second bridge circuit, wherein at least one circuit element associated with said first bridge circuit is rotated by forty-five degrees relative to at least one circuit element associated with said second bridge circuit.

14. A method for generating an offset voltage utilized in generating angular position estimates, said method comprising the steps of:
configuring a first bridge circuit to comprise a first plurality of resistors arranged in a bridge configuration;
configuring a second bridge circuit to comprise a second plurality of resistors arranged in a bridge configuration; and
coupling an offset voltage amplifier circuit to said first and second bridge circuits, wherein said offset voltage amplifier circuit generates an offset voltage that is utilized to generate angular position estimations.

15. The method of claim 14 further comprising the steps of:
coupling said first plurality of resistors to a first amplifier; and
generating a first voltage having a sinusoidal component thereof at an output of said first amplifier.

16. The method of claim 14 further comprising the steps of:
coupling said second plurality of resistors to a second amplifier; and
generating a second voltage having a cosine component thereof at an output of said second amplifier.

17. The method of claim 14 wherein said offset voltage amplifier circuit comprises at least one amplifier.

18. The method of claim 17 further comprising the step of:
coupling said at least one amplifier to a node to which at least two resistors are also coupled.

19. The method of claim 14 wherein said first bridge circuit comprises an AMR bridge circuit.

20. The method of claim 14 wherein said second bridge circuit comprises an AMR bridge circuit.

21. The method of claim 15 wherein said first plurality of resistors comprises at least four resistors.

22. The method of claim 16 wherein said second plurality of resistors comprises at least four resistors.

23. The method of claim 14 wherein said offset voltage comprises a common-mode offset voltage.

24. The method of claim 14 further comprising the step of:
centroidally collocating said first bridge circuit with said second bridge circuit.

25. The method of claim 24 further comprising the step of:
rotating at least one circuit element associated with said first bridge circuit by forty-five degrees relative to at least one circuit element associated with said second bridge circuit.

26. A method for generating an offset voltage utilized in generating angular position estimates, said method comprising the steps of:
configuring a first bridge circuit to comprise a first plurality of resistors arranged in a bridge configuration, wherein said first plurality of resistors is coupled to a first amplifier, such that a first voltage having a sinusoidal component thereof is generated at an output of said first amplifier;
configuring a second bridge circuit to comprise a second plurality of resistors arranged in a bridge configuration, wherein said second plurality of resistors is coupled to a second amplifier, such that a second voltage having a cosine component thereof is generated at an output of said second amplifier;
coupling an offset voltage amplifier circuit to said first and second bridge circuits, wherein said offset voltage amplifier circuit generates an offset voltage that is utilized to generate angular position estimations;
centroidally collocating said first bridge circuit with said second bridge circuit, wherein at least one circuit element associated with said first bridge circuit is rotated by forty-five degrees relative to at least one circuit element associated with said second bridge circuit;
configuring said offset voltage amplifier circuit to further comprise at least one amplifier; and
coupling said at least one amplifier to a node to which at least two resistors are also coupled.
